(19) United States
(12) Patent Application Publication
(10) Pub. No.: US 2024/0103236 A1
(43) Pub. Date: Mar. 28, 2024

(54) Optical Engine Including Fiber Deflection Unit and Method Forming the Same

(71) Applicant: Taiwan Semiconductor Manufacturing Co., Ltd., Hsinchu (TW)

(72) Inventors: Chih-Wei Tseng, Hsinchu (TW); Jui Lin Chao, New Taioei City (TW); Hsing-Kuo Hsia, Jhubei City (TW); Chen-Hua Yu, Hsinchu (TW)

(21) Appl. No.: 18/149,336

(22) Filed: Jan. 3, 2023

Related U.S. Application Data
(60) Provisional application No. 63/384,254, filed on Nov. 18, 2022.
(60) Provisional application No. 63/377,237, filed on Sep. 27, 2022.

(51) Int. Cl. G02B 6/42

(52) U.S. Cl. CPC G02B 6/4214; G02B 6/4243

(57) ABSTRACT

A method includes forming an optical engine, which includes a photonic die. The photonic die further includes a grating coupler. The method further includes forming a fiber unit including a fiber platform having a groove, and an optical fiber attached to the fiber platform. The optical fiber extends into the groove. The fiber platform further includes a reflector. The fiber unit is attached to the optical engine, and the reflector is configured to deflect a light beam, so that the light beam emitted by a first one of the optical fiber and the grating coupler is received by a second one of the optical fiber and the grating coupler.

### PRIORITY CLAIM AND CROSS-REFERENCE

This application claims the benefit of the following provisionally filed U.S. Patent application: Application No. 63/384,254, filed on Nov. 18, 2022, and entitled “Package Structure,” and Application No. 63/377,237, filed on Sep. 27, 2022, and entitled “Fibre Array Unit for COUPE with Optical Focus Lens for Grating Coupler,” which applications are hereby incorporated herein by reference.

### BACKGROUND

As the bandwidth requirement grows rapidly for high-performance computing systems, high-speed optical Input/Output (I/O) modules have been used increasingly. The optical I/O modules are often connected to light sources (laser) as the circuit driving sources.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-12 illustrate the intermediate stages in the formation of a package in accordance with some embodiments.

FIGS. 13-14 illustrate the intermediate stages in the formation of a package in accordance with some embodiments.

FIG. 15 illustrates a magnified view of a fiber deflection unit in accordance with some embodiments.

FIGS. 16A and 16B illustrate a cross-sectional view and a top view, respectively, of a lens in a recess in accordance with some embodiments.

FIG. 17 illustrates a magnified view of a light path including parts of a fiber deflection unit, a supporting substrate, and a grating coupler in accordance with some embodiments.

FIG. 18 illustrates a perspective view of a fiber deflection unit in accordance with some embodiments.

FIGS. 19A and 19B illustrate grooves in a fiber platform in accordance with some embodiments.

FIGS. 20-28 illustrate the cross-sectional views of fiber deflection units in accordance with some embodiments.

FIG. 29 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, an optical engine and a fiber deflection unit are formed. The fiber deflection unit includes a groove for holding an optical fiber, which is placed horizontally. A reflector in the fiber deflection unit is used to reflect light, so that light beam is deflected from horizontal to vertical, or from vertical to horizontal. By adopting the embodiments of the present application, optical fibers may be placed horizontally, and the alignment of the optical fibers is achieved by using grooves in the fiber deflection unit. The alignment of the horizontally placed optical fibers is thus much easier and more accurate than vertically placed optical fibers.

The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements.

Although method embodiments may be discussed as being performed in a particular order, other method embodiments may be performed in any logical order.

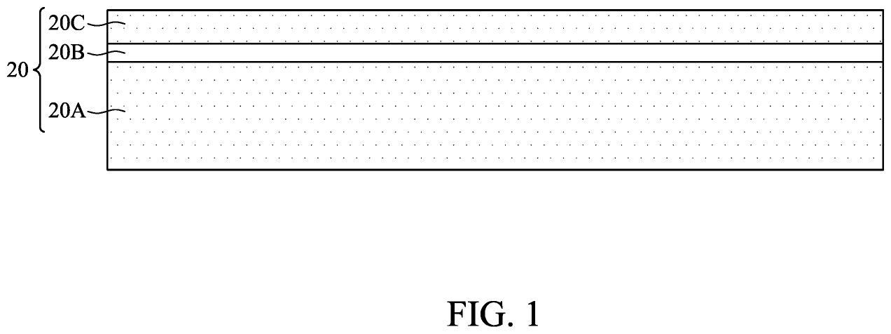

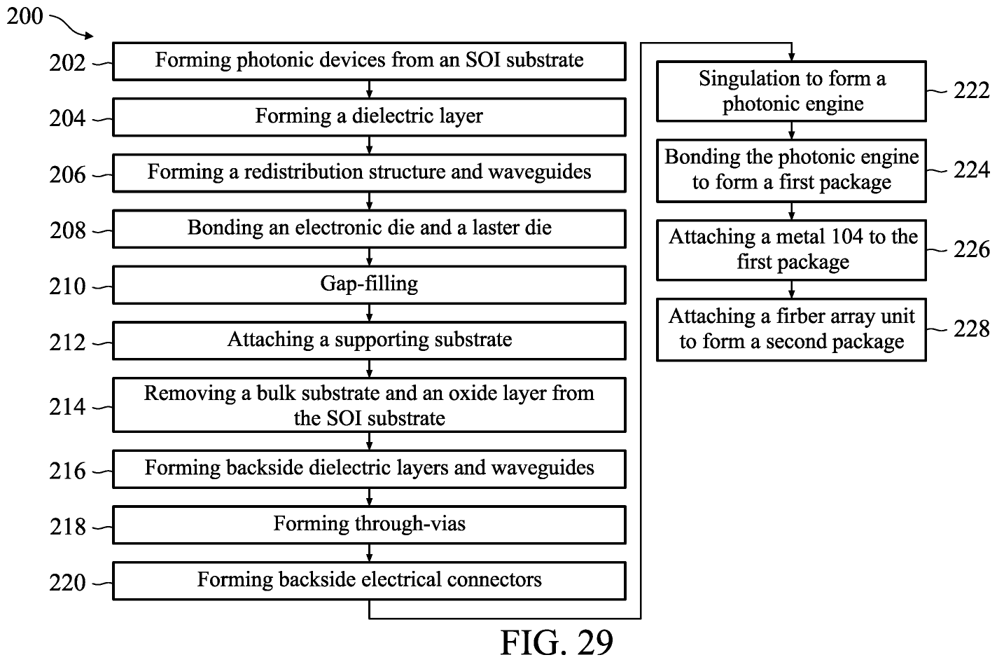

FIGS. 1-12 illustrate the cross-sectional views of intermediate stages in the formation of a package in accordance with some embodiments of the present disclosure. The corresponding processes are also reflected schematically in the process flow 200 as shown in FIG. 29.

Referring to FIG. 1, substrate 20 is provided. In accordance with some embodiments, substrate 20 is a Silicon-on-Insulator (SOI) substrate including semiconductor layer 20A, dielectric layer 20B over semiconductor layer 20A, and photonic layer 20C over dielectric layer 20B. Each of semiconductor layer 20A, dielectric layer 20B, and photonic layer 20C is a blanket layer. In accordance with some embodiments, semiconductor layer 20A includes a semiconductor substrate such as a silicon substrate. Dielectric layer 20B may be formed of or comprise silicon oxide. In accordance with some embodiments, photonic layer 20C is formed of or comprises silicon. In accordance with alternative embodiments, photonic layer 20C is formed of or comprises a III-V compound semiconductor material, lithium niobate, a polymer, or the like. Photonic layer 20C is referred to as silicon layer 20C hereinafter, while it may also be formed of other materials, as aforementioned.

Dielectric layer 20B may have a thickness in the range between about 0.5 μm and about 4 μm. Silicon layer 20C may have a thickness in the range between about 0.1 μm and about 1.5 μm. Substrate 20 may be referred to as having a front side or front surface (e.g., the side facing upwards in FIG. 1), and a backside or back surface (e.g., the side facing downwards in FIG. 1). The front side of the substrate 20 is also referred to as the front side of the resulting photonic wafer and photonic die that are formed in subsequent processes.

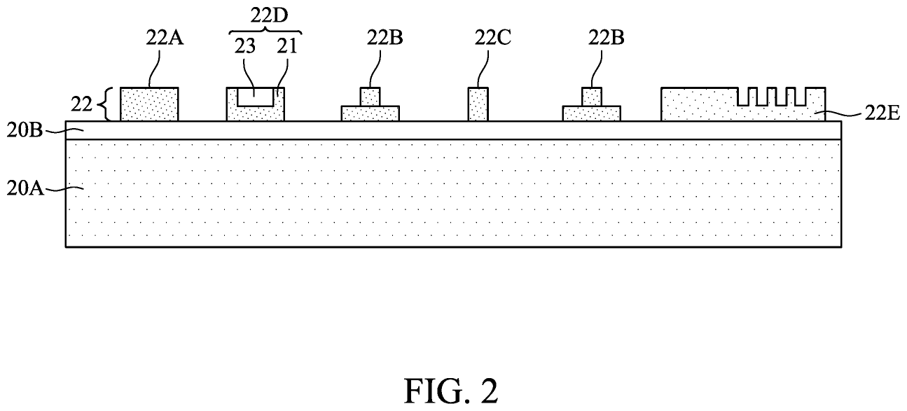

Referring to FIG. 2, silicon layer 20C is patterned to form a plurality of photonic devices 22, which are alternatively referred to as optical devices or silicon devices. The respective process is illustrated as process 202 in the process flow 200 as shown in FIG. 29. Silicon layer 20C may be patterned using suitable photolithography and etching techniques, which may involve etching processes using photoresists to define patterns.

Some examples of the photonic devices 22 include waveguide(s) 22A, slab waveguide(s) 22B, germanium modulator(s) 22D, grating coupler(s) 22E, photodetectors (not shown), and/or the like. Tip waveguides 22C may also be formed, which are narrow waveguides, for example, having widths in the range between about 1 nm and about 200 nm. A photodetector may be optically coupled to one of the waveguides 22A to detect optical signals within the waveguide and generate electrical signals corresponding to the optical signals. In accordance with other embodiments, photonic devices 22 may include other active or passive components, such as laser diodes, optical signal splitters, or other types of photonic structures or devices.

Modulators may also be formed, and germanium modulator 22D is shown an example of the modulators. The formation of germanium modulator 22D may include forming silicon component 21 when silicon layer 20C is patterned, and forming germanium region 23 in the recess in silicon component 21. Modulators such as germanium modulator 22D may be used for electrical-to-optical signal modulation and transversion. The modulators may receive electrical signals and modulate optical power within a waveguide to generate corresponding optical signals. In this manner, photonic devices 22 may input optical signals from, or output optical signal to, waveguides.

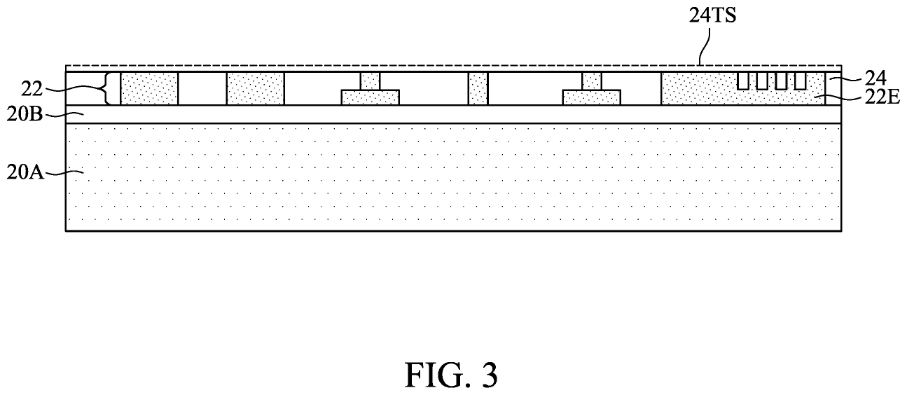

Referring to FIG. 3, dielectric layer 24 is formed. The respective process is illustrated as process 204 in the process flow 200 as shown in FIG. 29. The formation process may include depositing a dielectric layer, and performing a planarization process such as a Chemical Mechanical Polish (CMP) process or a mechanical grinding process. In accordance with some embodiments, the top surface of dielectric layer 24 is level with the top surfaces of photonic devices 22. In accordance with alternative embodiments, the top surface of dielectric layer 24 is higher than the top surfaces of photonic devices 22, and the corresponding top surface of dielectric layer 24 is illustrated using dashed line 24TS. Dielectric layer 24 may be formed of or comprise an oxide such as silicon oxide in accordance with some embodiments, while other dielectric materials that are transparent to light may also be used.

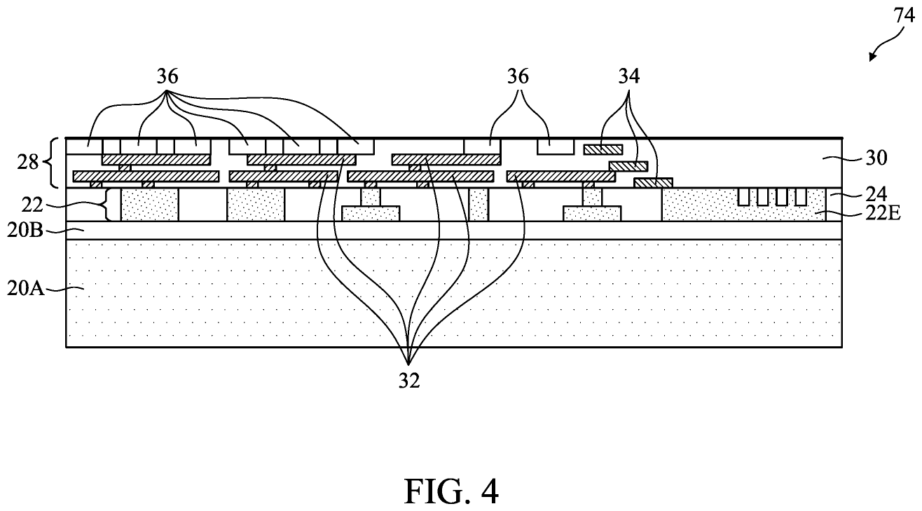

Referring to FIG. 4, redistribution structure 28 is formed over dielectric layer 24. The respective process is illustrated as process 206 in the process flow 200 as shown in FIG. 29. Redistribution structure 28 includes dielectric layers 30 and conductive features 32 formed in dielectric layers 30. Conductive features 32 provide electrical interconnections and electrical routing. Conductive features 32 are electrically connected to modulators, photodetectors, and or the like. Dielectric layers 30 may be, for example, insulating layers and/or passivating layers, and may comprise silicon oxide, silicon nitride, or other dielectric materials that are transparent to light. Dielectric layers 30 may be formed through damascene processes. Bond pads 36 may be formed in the topmost layer of dielectric layers 30.

In dielectric layers 30, waveguides 34 may also be formed. The respective process is also illustrated as process 206 in the process flow 200 as shown in FIG. 29. In accordance with some embodiments, waveguides 34 are formed of silicon nitride, and hence are referred to as nitride waveguide 34 hereinafter. Nitride waveguides 34, although the name, may also include other photonic structures such as grating couplers and edge couplers, which allow optical signals to be transmitted or processed. Silicon nitride has a higher dielectric constant than silicon, and thus a nitride waveguide may have a greater internal confinement of light than a silicon waveguide. This may also allow the performance or leakage of nitride waveguides to be less sensitive to process variations, less sensitive to dimensional uniformity, and less sensitive to surface roughness (e.g., edge roughness or linewidth roughness). Throughout the description, the structure shown in FIG. 4 is referred to as Photonic Integrated Circuit (PIC) wafer 74.

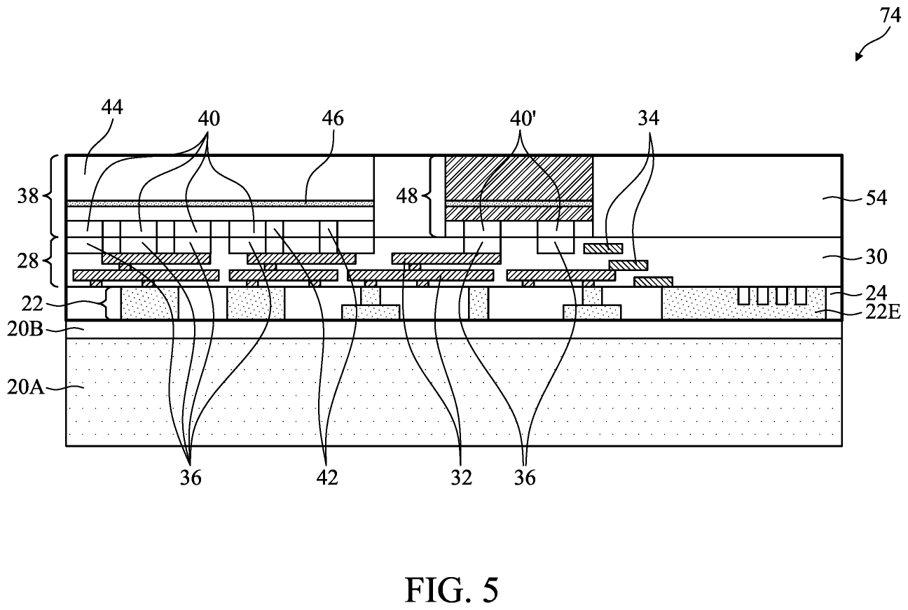

Referring to FIG. 5, electronic die 38 is bonded to redistribution structure 28. The respective process is illustrated as process 208 in the process flow 200 as shown in FIG. 29. Electronic die 38 may also be referred to as an Electronic Integrated Circuit (EIC) die. Although one electronic die 38 is illustrated, a plurality of electronic dies 38 that are identical to each other may be bonded to interconnect structure 28. Electronic dies 38 may include device dies that communicate with photonic devices 22 using electrical signals. Electronic die 38 includes semiconductor substrate 44, integrated circuits 46 (schematically illustrated), and electrical connectors 40, which may be in surface dielectric layer 42. Electrical connectors 40 may include, for example, conductive pads, conductive pillars, or the like.

In accordance with some embodiments, electronic die 38 is bonded to redistribution structure 28 through dielectric-to-dielectric bonding, metal-to-metal bonding, the combination of dielectric-to-dielectric bonding and metal-to-metal bonding, solder bonding, or the like. For example, surface dielectric layer 42 in electronic die 38 may be bonded to the top dielectric layer 30 in interconnect structure 28 through fusion bonding, while electric connectors 40 in electronic die 38 may be bonded to bond pads 36 through metal-to-metal direct bonding.

Integrated circuits 46 have the function of interfacing with photonic devices 22, and may include the circuits for controlling the operation of photonic devices 22. For example, integrated circuits 46 may include controllers, drivers, amplifiers, the like, or combinations thereof. Electronic die 38 may also include a Central Processing Unit (CPU). In accordance with some embodiments, integrated circuits 46 include the circuits for processing electrical signals received from photonic devices 22. Electronic die 38 may also control high-frequency signaling of photonic devices 22 according to the electrical signals (digital or analog) received from another device or die. In accordance with some embodiments, electronic die 38 may provide Serializer/Deserializer (SerDes) functionality, so that electronic die 38 may act as a part of an I/O interface between optical signals and electrical signals.

In accordance with some embodiments, laser die 48 is bonded to redistribution structure 28. In accordance with alternative embodiments, no laser die is bonded to redistribution structure 28. Laser die 48 may be bonded to redistribution structure 28 through electrical connectors 40′, which may comprise metal pads, metal pillars, or the like. The bonding method may be selected from the same group of candidate bonding methods for bonding electronic die 38.

Laser die 48 may receive electrical signal through electrical connectors 40′ and 36, and generate optical signals from the electrical signals. The optical signals may be projected onto some of the photonic devices 22 such as grating couplers, which optical signals are transferred through waveguides 34.

Further referring to FIG. 5, gap-filling material 54 is formed to encapsulate electronic die 38 and laser die 48. The respective process is illustrated as process 210 in the process flow 200 as shown in FIG. 29. Gap-filling material 54 may be formed of or comprise silicon oxide, silicon nitride, a polymer, the like, multi-layers thereof, and/or a combination thereof. Gap-filling material 54 may be formed through Chemical Vapor Deposition (CVD), Atomic Layer Deposition (ALD), spin-on coating, Flowable Chemical Vapor Deposition (FCVD), or the like. Gap-filling material 54 may be a material (e.g., silicon oxide) that is transparent to light at wavelengths suitable for transmitting optical signals.

Gap-filling material 54 may be planarized using a planarization process such as a CMP process, a mechanical grinding process, or the like. In accordance with some embodiments, the planarization process may expose electronic die 38 and laser die 48, with the top surfaces of electronic die 38, laser die 48, and gap-filling material 54 being coplanar. After the planarization process, the top surfaces of the substrates of electronic die 38 and laser die 48 and the top surface of gap-filling material 54 may be revealed in accordance with some embodiments. Alternatively, there is a thin layer of gap-filling material 54 covering electronic die 38 and laser die 48 after the planarization process.

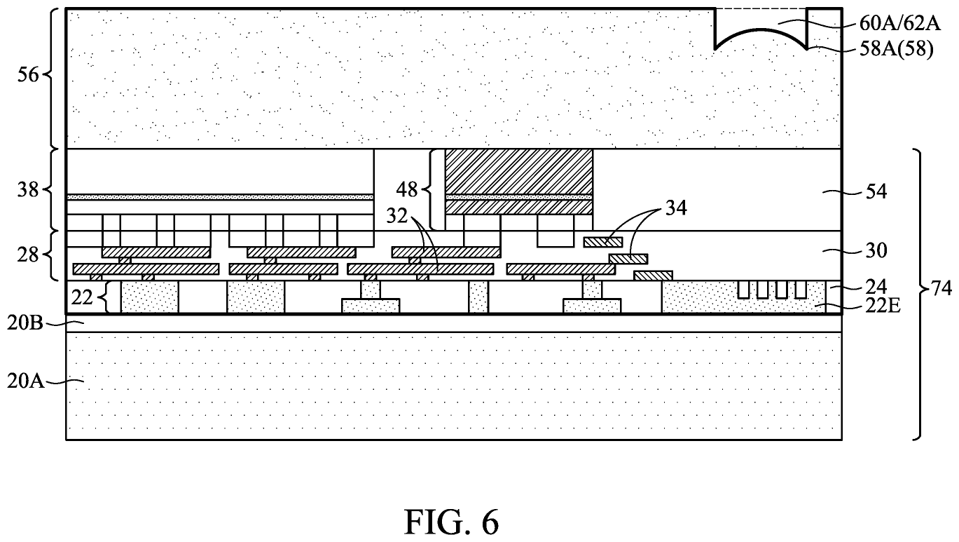

FIG. 6 illustrates the attachment of supporting substrate 56. The respective process is illustrated as process 212 in the process flow 200 as shown in FIG. 29. In accordance with some embodiments, supporting substrate 56 is or comprises a silicon substrate, which may be a crystalline silicon substrate. A silicon-containing dielectric layer (not shown, which may be a part of gap-filling material 54 or a layer formed in supporting substrate 56) may be used to bond supporting substrate 56 to the semiconductor substrate of electronic die 38. The silicon-containing dielectric layer may be formed of or comprise silicon oxide, silicon oxynitride, silicon carbo-nitride, or the like. Alternatively, the silicon in supporting substrate 56 physically contacts, and is bonded to, electronic die 38, laser die 48, and gap-filling material 54. The bonding may be performed through fusion bonding, with Si—O—Si bonds being generated.

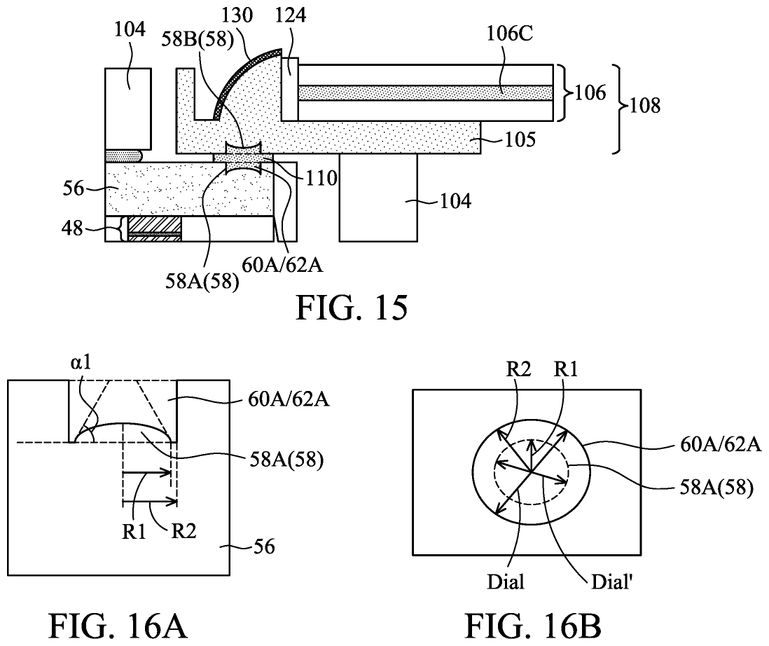

In accordance with some embodiments, lens 58A (also referred to as lens 58) is formed in supporting substrate 56. The formation process may include etching supporting substrate 56 to form recess 60A. A portion of the supporting substrate 56 facing and underlying recess 60A is curved to form lens 58A. The details of lens 58A are discussed subsequently referring to FIGS. 16A and 16B. In accordance with some embodiments, recess 60A is filled with transparent filling material 62A, which may be formed of or comprise silicon oxide, silicon oxynitride, or the like. A planarization process such as a CMP process or a mechanical grinding process may be performed to level the top surfaces of supporting substrate 56 and transparent filling material 62A with each other. In accordance with alternative embodiments, recess 60A is not filled at this time.

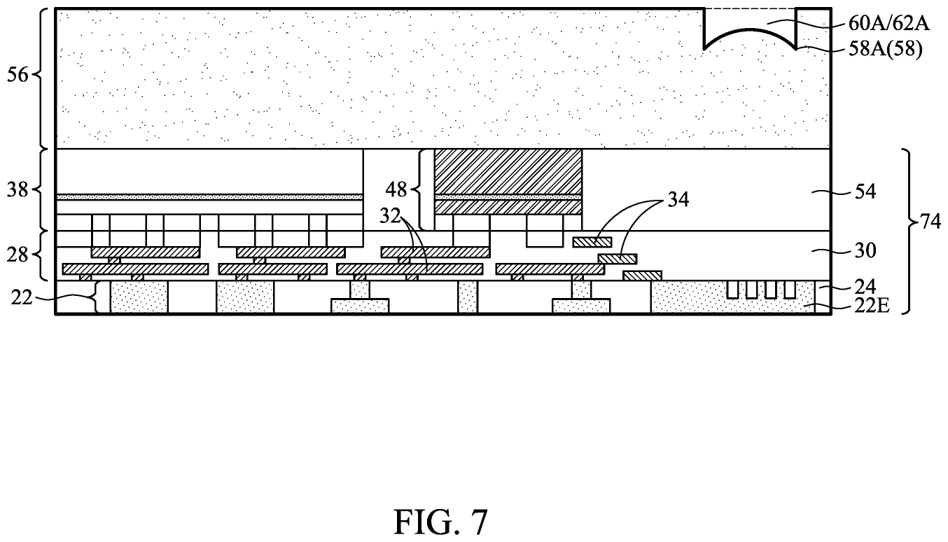

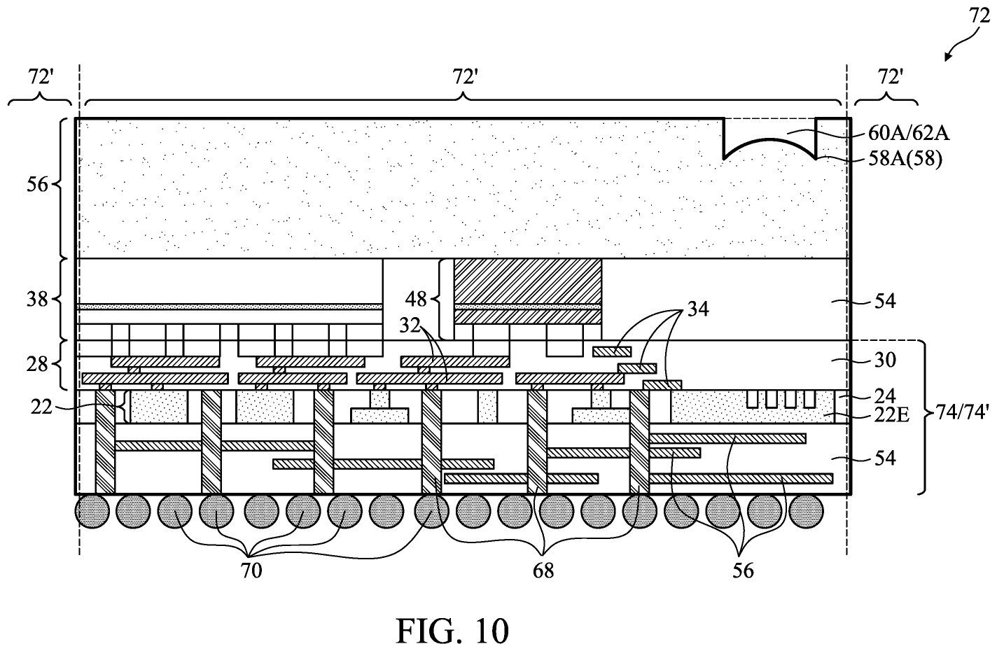

Next, semiconductor layer 20A may be removed. The respective process is illustrated as process 214 in the process flow 200 as shown in FIG. 29. The resulting structure is shown in FIG. 7. Semiconductor layer 20A may be removed using a polishing process, an etching process, a combination thereof, or the like. In accordance with some embodiments, dielectric layer 20B is also removed, so that the bottom surfaces of dielectric layer 24 and photonic devices 22 are revealed. The respective process is also illustrated as process 214 in the process flow 200 as shown in FIG. 29. In accordance with alternative embodiments, dielectric layer 20B is thinned, but not removed. The remaining thin layer of dielectric layer 20B may protect photonic devices 22 from the damaged that may be caused by the removal of dielectric layer 20B. The thin layer of dielectric layer 20B may remain in the photonic wafer 74 (FIG. 10), without affecting the functionality of the resulting photonic wafer 74 (and photonic die 74′).

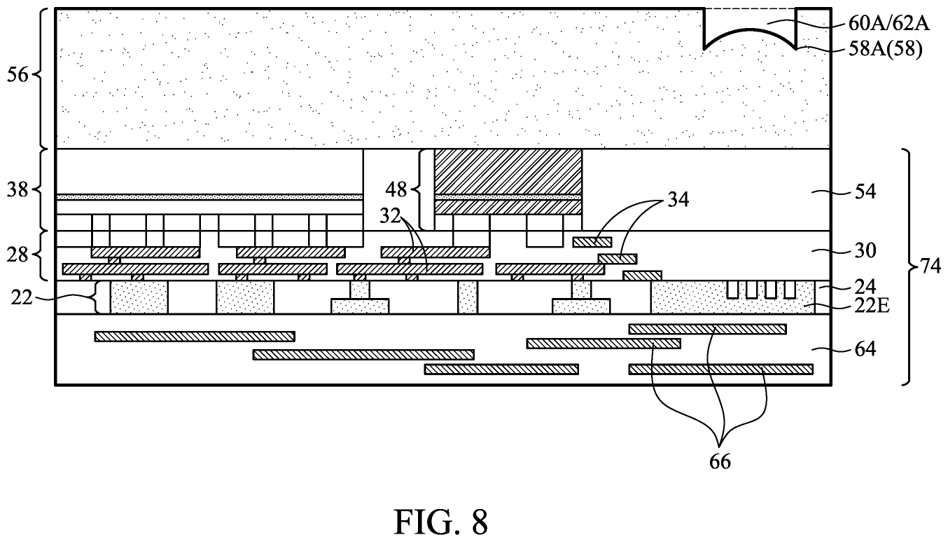

In subsequent processes, as shown in FIG. 8, backside dielectric layers 64 are formed on the backside of photonic devices 22. Nitride waveguides 66 are also formed in dielectric layers 64. The respective process is illustrated as process 216 in the process flow 200 as shown in FIG. 29. The formation of nitride waveguides 66 may include a deposition process, followed by a patterning process through etching. The deposition process may include CVD, PECVD, Low-Pressure Chemical Vapor Deposition (LPCVD), PVD, or the like. Nitride waveguides 66 may be formed of or comprise silicon nitride, silicon oxynitride, or the like. Alternatively, instead of forming nitride waveguides 66, polymer waveguides may be formed.

Dielectric layers 64 may be formed of or comprise a light-transparent material(s) such as silicon oxide, a spin-on glass, or the like. Dielectric layers 64 may be formed using CVD, PVD, spin-on coating, or the like, while other applicable processes may be used. In accordance with some embodiments, a planarization process such as a CMP process or a mechanical grinding process is used to remove excess material of each of dielectric layers 64. After the planarization, dielectric layers 64 may have a surface (the illustrated bottom surface) coplanar with a surface of the corresponding nitride waveguides 66. Alternatively, dielectric layers 64 may be thicker than the corresponding nitride waveguides 66, so that after the planarization process, the nitride waveguides 66 are embedded in the corresponding dielectric layer 64.

Nitride waveguides 66 may be optically coupled to photonic devices 22 through light projection and/or through Evanescent coupling. Nitride waveguides 66 may also be optically inter-coupled through Evanescent coupling. In the Evanescent coupling, when two waveguides 66 are parallel and adjacent to each other with a small distance, the light in one of the waveguides 66 may be coupled into the other waveguide.

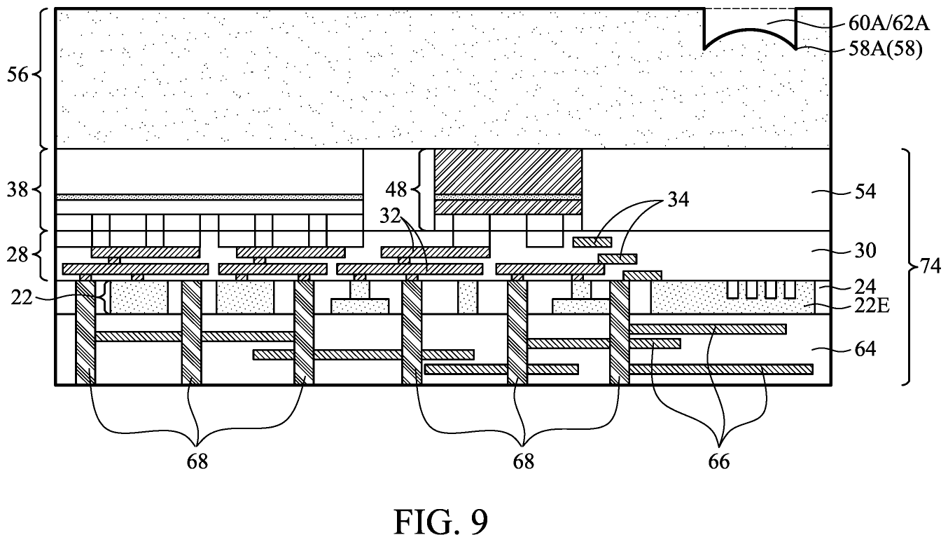

Referring to FIG. 9, through-vias 68 are formed to penetrate through dielectric layers 64 and dielectric layer 24, and electrically connect to conductive features 32 in interconnect structure 28. The respective process is illustrated as process 218 in the process flow 200 as shown in FIG. 29. The formation process may include etching-through layers 54 and dielectric layer 24 to form via openings, and to reveal conductive features 32, filling the via openings with conductive materials (such as TiN, TaN, Ti, Ta, Cu, W, Co, or the like), and performing a planarization process. There may be, or may not be, dielectric liners formed encircling through-vias 68.

Referring to FIG. 10, electrical connectors 70 are also formed. The respective process is illustrated as process 220 in the process flow 200 as shown in FIG. 29. Electrical connectors 70 are electrically coupled to RDLs 32 through through-vias 68. The structure shown in FIG. 10, which structure is a reconstructed wafer, is referred to as reconstructed wafer 72. Reconstructed wafer 72 includes photonic wafer 74, a plurality of electronic dies 38, and a plurality of laser dies 48 therein.

In a subsequent process, a singulation process is performed to saw reconstructed wafer 72 into a plurality of packages 72′ that are identical to each other. The packages 72′ are also referred to as optical engines 72′. The respective process is illustrated as process 222 in the process flow 200 as shown in FIG. 29. Photonic wafer 74 is sawed into photonic dies 74′. Each of optical engines 72′ may include photonic die (PIC) 74′ and an electronic die (EIC) 38 therein.

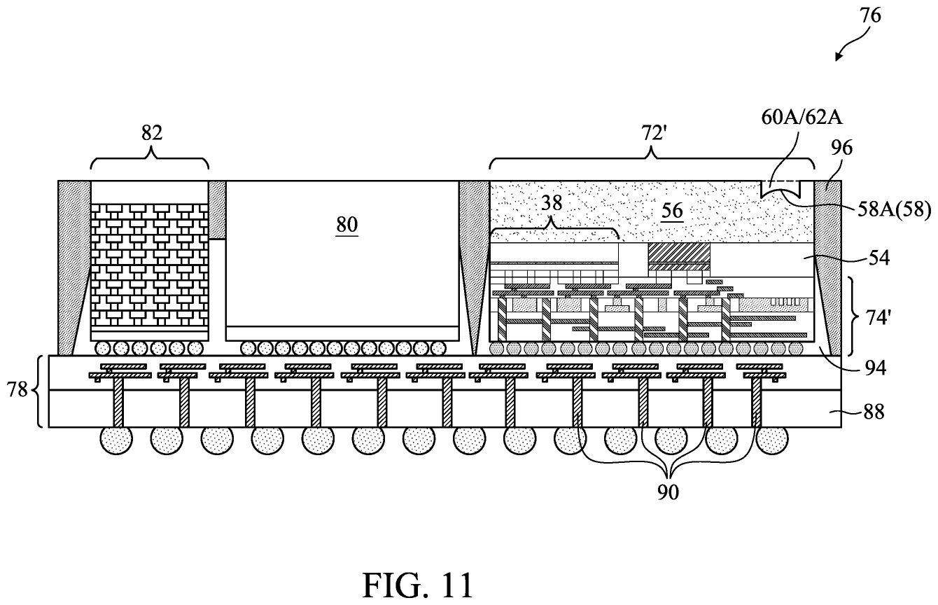

Referring to FIG. 11, package 76 is formed to incorporate optical engine 72′ therein. In accordance with some embodiments, package 76 includes package component 78. Optical engine 72′ and package components 80 and 82 are bonded to package component 78. The bonding may be performed through dielectric-to-dielectric bonding, metal-to-metal bonding, the combination of dielectric-to-dielectric bonding and metal-to-metal bonding, solder bonding, or the like. Package component 78 may be or may comprise an interposer, a package substrate, another package, or the like.

Package component 78 may be an interposer selected from, and not limited to, a silicon-based interposer, an organic interposer (also referred to as an RDL interposer), a Local Silicon Interconnect (LSI) interposer including an LSI die(s) built therein, or the like. FIG. 11 illustrates a silicon-based interposer 78 as an example. The silicon-based interposer 78 may include a silicon substrate 88 and through-silicon vias 90 (TSVs, also referred to as through-vias (TVs)) penetrating through the silicon substrate 88. When being an organic interposer, package component 78 may include organic dielectric layers, and RDLs built in the dielectric layers. When being an LSI interposer, package component 78 may include LSI die(s) used for interconnecting optical engine 72′ and package components 80 and 82.

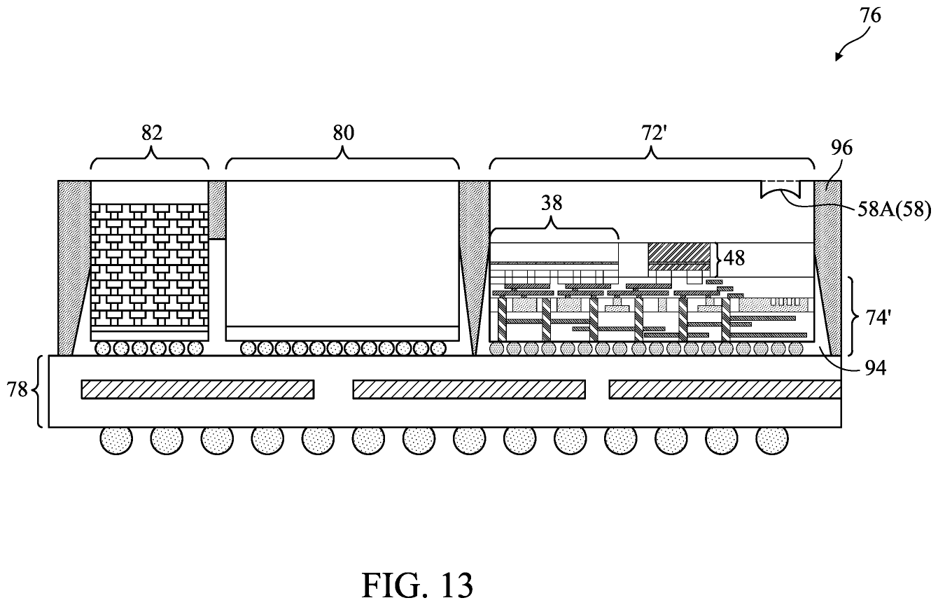

Further referring to FIGS. 11 and 13, in accordance with some embodiments, each of package components 80 and 82 may be a device die, a package with a device die(s) packaged therein, a System-on-Chip (SoC) die including a plurality of integrated circuits (or device dies) integrated as a system, or the like. The device dies in package components 80 and 82 may be or may comprise logic dies, memory dies, input-output dies, Integrated Passive Devices (IPDs), or the like, or combinations thereof. For example, the logic device dies in package components 80 and 82 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in package components 80 and 82 may include Static Random-Access Memory (SRAM) dies, Dynamic Random-Access Memory (DRAM) dies, or the like. The device dies in package components 80 and 82 may include semiconductor substrates and interconnect structures.

In accordance with some example embodiments, package component 80 is a logic die, which may be an Application-Specific Integrated Circuit (ASIC) die. Package component 82 may be a memory stack such as a High-Performance Memory (HBM) stack. Package component 82 may include memory dies forming a die stack, and an encapsulant (such as a molding compound) encapsulating the memory dies therein.

As shown in FIGS. 11 and 13, underfills 94 are dispensed into the gaps between optical engine 72′, packages components 80 and 82, and the underlying package component 78. Molding compound 96 is also dispensed to encapsulate optical engine 72′ and packages components 80 and 82 therein.

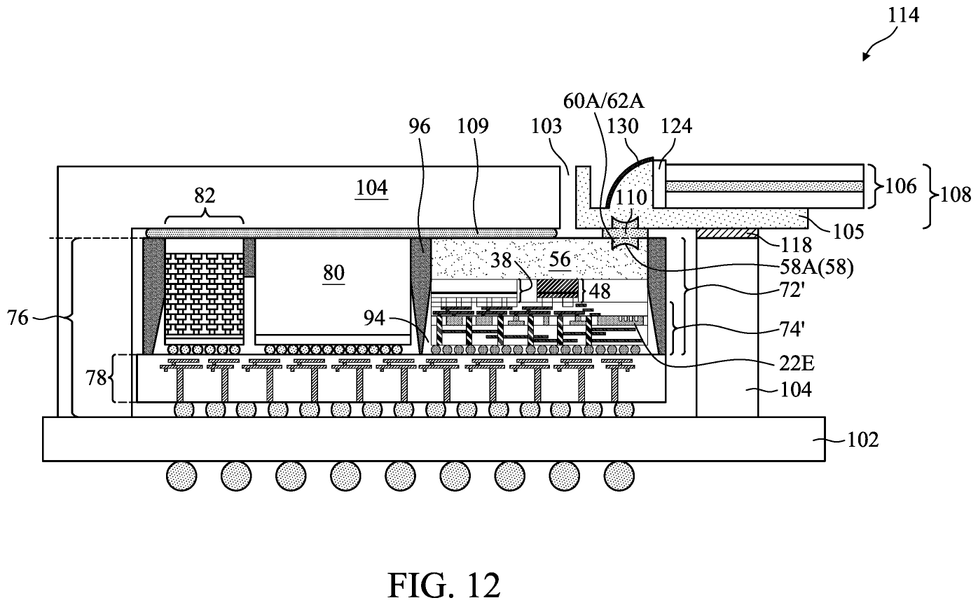

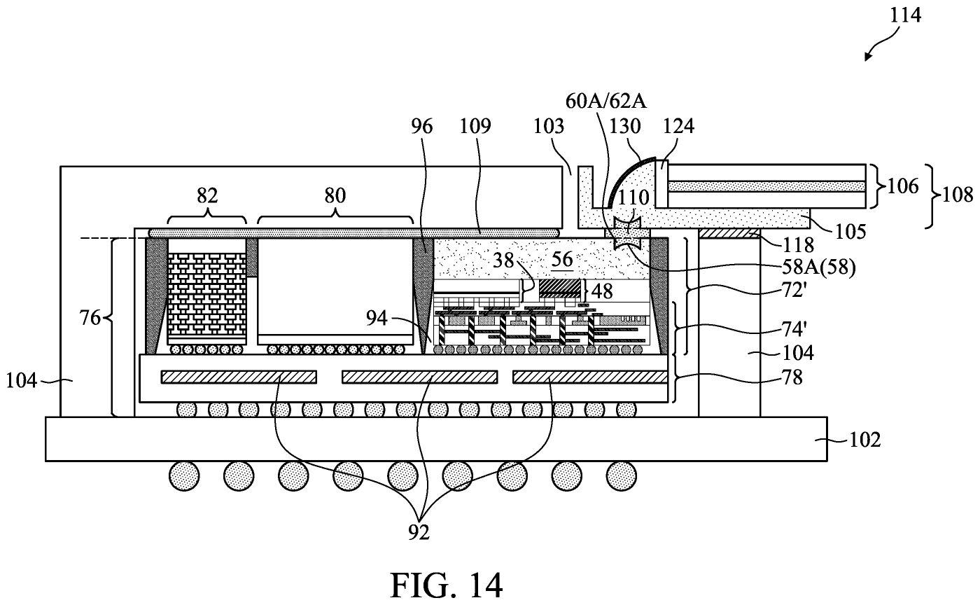

FIGS. 12 and 14 illustrate the bonding of package 76 to package component 102. Package component 102 may be or may comprise a package substrate, a printed circuit board, another package, or the like. Metal lid 104 is attached to package component 102, for example, through an adhesive (not shown). Thermal Interface material (TIM) 109 is dispensed on the top of package components 80 and 82, and joins metal lid 104 to package components 80 and 82. In the illustrated cross-sectional view, metal lid 104 includes a left portion on the left side of package 76, and a right portion on the right side of package 76. The illustrated left portion and right portion may be portions of a metal ring portion of metal lid 104, wherein the metal ring portion may be a full ring. In the cross-sectional view, metal lid 104 includes a cover portion, with an opening 103 formed in the cover portion.

Further referring to FIGS. 12 and 14, an optical fiber(s) 106 is signally coupled to optical engine 72′ through optical fiber platform 105. Package 114 is thus formed. In FIGS. 12 and 14, fiber platform 105 and optical fibers 106 are shown schematically, and the details are discussed subsequently referring to FIGS. 15, 16A, 16B, 18, 19A, and 19B. In accordance with some embodiments, there are a plurality of optical fibers 106 attached to fiber platform 105. Fiber platform 105 and optical fibers 106 are collectively referred to as Fiber deflection unit 108, Fiber Attachment unit (FAU) 108, or fiber unit 108. The total number of optical fibers 106 in a fiber unit 108 may range from 2 to 40, while more optical fibers 106 may be attached. In accordance with alternative embodiments, there is a single optical fiber 106 in fiber unit 108. The optical fibers 106 may be optically coupled to grating coupler(s) 22E. Throughout the description, fiber unit 108 is also referred to as FAU 108, which may be a multi-optical-fiber or a single-optical-fiber unit.

In accordance with some embodiments, index matching glue 110 is dispensed and then cured to attach FAU 108 to optical engine 72′. The refractive index of index matching glue 110 may be in the range between about 1.4 and 1.5. FAU 108 may also be attached to metal lid 104 through adhesive 118. Accordingly, FAU 108 is fixed on optical engine 72′ and metal lid 104.

FIG. 15 illustrates a magnified view of a portion of the package 114 in FIG. 12 or FIG. 14. In accordance with some embodiments, the recess 60A, under which lens 58A is formed, is filled with transparent filling material 62A. Index matching glue 110 is dispensed over and contacting both of transparent filling material 62A and supporting substrate 56. In accordance with alternative embodiments, the recess 60A is not filled with transparent filling material 62A, and index matching glue 110 fills recess 60A. Index matching glue 110 may physically separate FAU 108 from supporting substrate 56.

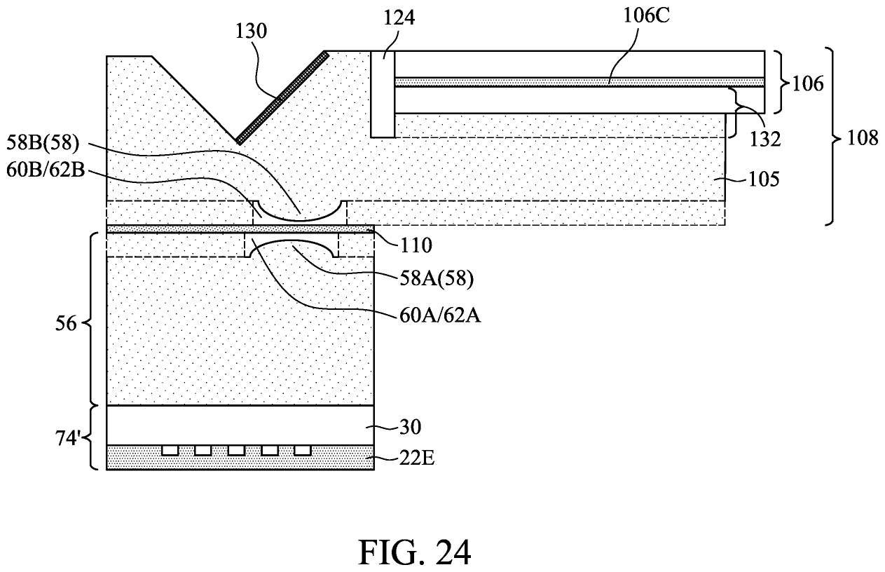

In accordance with alternative embodiments, there is no index matching glue 110, and supporting substrate 56 physically contacts FAU 108. In which embodiments, fiber platform 105 may be bonded to supporting substrate 56 through Si—Si bonds or Si—O—Si bonds. Alternatively, fiber platform 105 may be in contact with supporting substrate 56 without bonds formed in between. There may be, or may not be, another lens 58B (58) (also refer to FIG. 24) in the bottom portion of FAU 108.

FIG. 16A illustrates a cross-sectional view of lens 58A in accordance with some embodiments. Lens 58A occupies a first region, which is referred to as a clear aperture since the surface of this part of the supporting substrate 56 is smooth and has low loss of light. Recess 60A occupies a second region, which is referred to as a mechanical aperture. The ratio R1/R2, which is the ratio of radius R1 of the clear aperture to the radius R2 of the mechanical aperture, may be in the range between about 0.5 and about 1.0. Lens 58A may have a tangent angle α1, which may be in the range between about 5 degrees and about 15 degrees.

FIG. 16B illustrates a top view of recess 60A and lens 58A. In accordance with some embodiments, the top-view shapes of recess 60A and lens 58A are circles, which have uniform radius R1 and uniform radius R2 measuring in all directions. In accordance with alternative embodiments, the top-view shapes of recess 60A and lens 58A are quasi-circular, with radius R1 and radius R2 in different directions being different from, but close to, each other. For example, the variation of radius R1 (and the variation of radius R2) in different directions may be smaller than about 15 percent.

In accordance with some embodiments, the diameter Dia1 of mechanical aperture may be in the range between about 235 μm and about 275 μm. The diameter Dia1′ of lens 58 may be in the range between about 50 μm and about 275 μm.

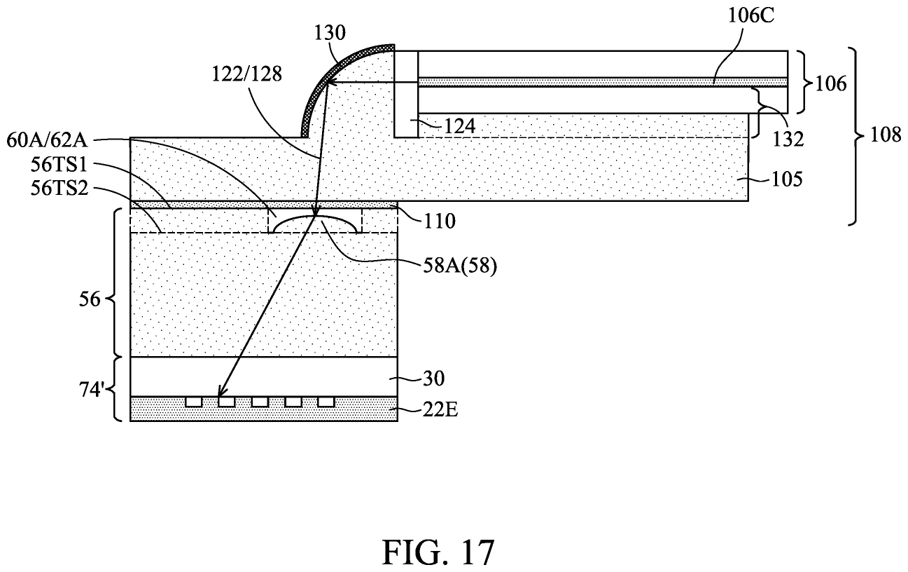

FIG. 17 illustrates a magnified view of a portion of FAU 108 as shown in FIG. 12 or FIG. 14 in accordance with some embodiments. The illustrated portion includes a light path 122 between optical fiber 106 and grating coupler 22E. The corresponding light beam 128 may be projected from optical fiber 106, and received by grating coupler 22E, or conversely, projected from grating coupler 22E, and received by optical fiber 106. In the following discussion, it is assumed that the light beam 128 is projected from optical fiber 106 and received by grating coupler 22E, while it is appreciated that the light may travel in an opposite direction.

In accordance with some embodiments, each of the lens 58A and other lens 58 discussed throughout the description may be formed in a recess, or may be a protruding lens not formed in recess. For example, FIG. 17 uses dashed lines to represent some portions of supporting substrate 56 that may or may not exist. When the dashed portions exist, the respective lens 58A is in a recess that is recessed from planar top surface 56TS1 of supporting substrate 56. Otherwise, when the dashed portions do not exist, the respective lens 58A is a protruding lens protruding higher than the planar top surfaces 56TS2 of supporting substrate 56.

As shown in FIG. 17, index matching glue 124 is also used to fill the space between fiber platform 105 and optical fiber 106, so that the light beam 128 projected from optical fiber 106 has reduced loss. Index matching glue 124 also has the function of fixing optical fiber 106 in position. In accordance with some embodiments, reflector 130 is coated on a sidewall surface of fiber platform 105 to form a reflector (deflector). Reflector 130 may be formed of a metallic material, which may be formed of or comprise Cu, Al, Ta, Ti, TaN, TiN, W, silver, or the like, or combinations thereof.

In accordance with some embodiments, light beam 128 is emitted out of optical fiber 106 in a horizontal direction. Light beam 128 is reflected by reflector 130, and is deflected from the horizontal direction to a vertical direction. Light beam 128 is then converged by lens 58A, and is received by grating coupler 22E.

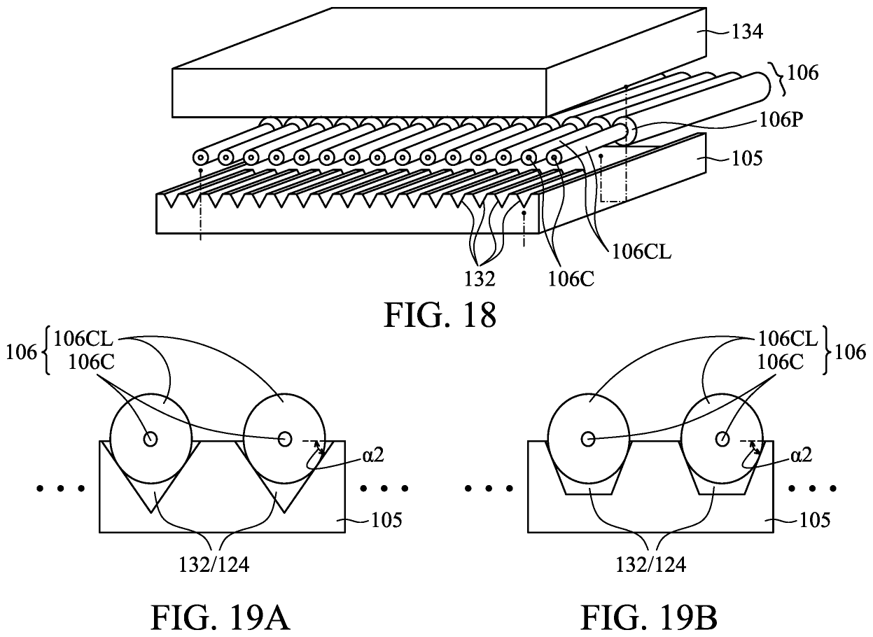

FIG. 18 illustrates a perspective view of some portions of optical fibers 106 and fiber platform 105, and illustrates how optical fibers 106 are fixed on fiber platform 105. In accordance with some embodiments, an optical fiber 106 includes protection layer (buffer layer) 106P, cladding layer 106CL, and core 106C. Core 106C has a first refractive index, and cladding layer 106CL has a second refractive index lower than the first refractive index to achieve total reflection. In accordance with some embodiments, core 106C is transparent, and may be formed of or comprises a polymer (for example, with a refractive index equal to about 1.44). Cladding layer 106CL may be formed of silicon oxide (with a refractive index equal to about 1.43).

Fiber platform 105 includes a plurality of grooves 132, each corresponding to one of optical fibers 106. The front portions of cladding layers 106CL and cores 106C are placed in grooves 132, so that they are fixed in positions. Optical glue 124 may also be filled into grooves 132 to attach optical fibers 106 to fiber platform 105. Protection layers 106P may be stripped off from the front portions of cladding layers 106CL and cores 106C in grooves 132, so that the front portions of optical fibers 106 may fit grooves 132. The back portions of optical fibers 106 outside of grooves 132 may include protection layers 106P. Cover 134 may be used to fix optical fibers 106 in the respective grooves 132. It is appreciated that FIG. 18 illustrates the positions of features before the assembly of fiber platform 105, fibers 106, and cover 134. In the assembly process, fibers 106 is pressed down and fixed in positions by cover 134 and optical glue 124.

In accordance with some embodiments, the fiber platform 105 as shown in FIGS. 17 and 18 is an integrated unit. The integrated unit, which includes a first portion for forming grooves 132, and a second portion on which reflector 130 is formed, with no distinguishable interface between the first portion and the second portion. In accordance with some embodiments, fiber platform 105 is formed of silicon, glass, or the like.

FIG. 19A illustrates a cross-sectional view of grooves 132 and fibers 106 in accordance with some embodiments. The grooves 132 may have triangular cross-sectional shapes. For example, fiber platform 105 may be formed of crystalline silicon. Due to the lattice structure of silicon, an etching process may be performed to etch fiber platform 105 in order to form the grooves 132 as shown in FIG. 19A. The sidewalls of grooves 132 have tilt angle α2, which may be in the range between about 25 degrees and about 75 degrees, and may be equal to 54.7 degrees.

FIG. 19B illustrates a cross-sectional view of grooves 132 and fibers 106 in accordance with alternative embodiments. The grooves 132 may have trapezoidal cross-sectional shapes. For example, an etching process may be performed to etch fiber platform 105 in order to form the grooves 132 as shown in FIG. 19B. The trapezoidal cross-sectional shape may be achieved by terminating the etching process before the opposite sidewalls of grooves 132 meet each other. The sidewalls of grooves 132 may also have tilt angle α2, which may be in the range between about 25 degrees and about 75 degrees, and may be equal to 54.7 degrees.

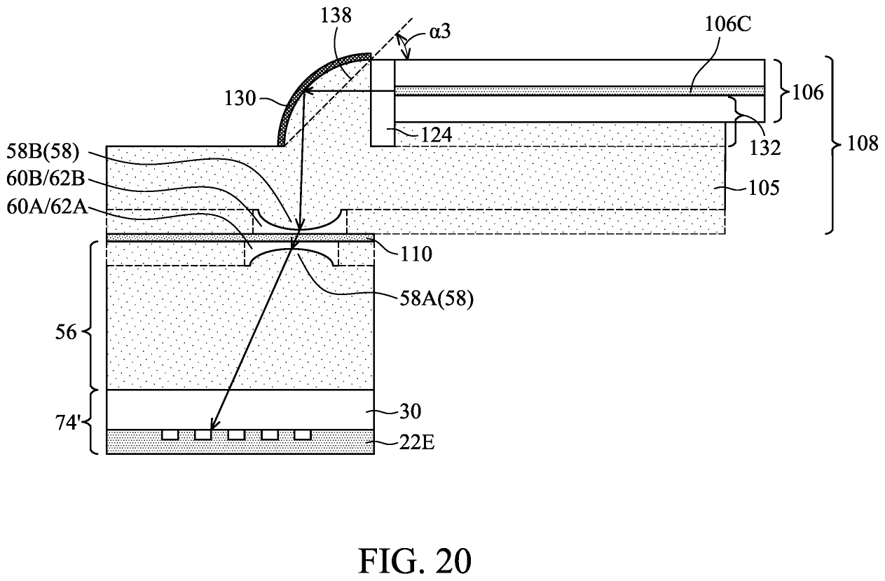

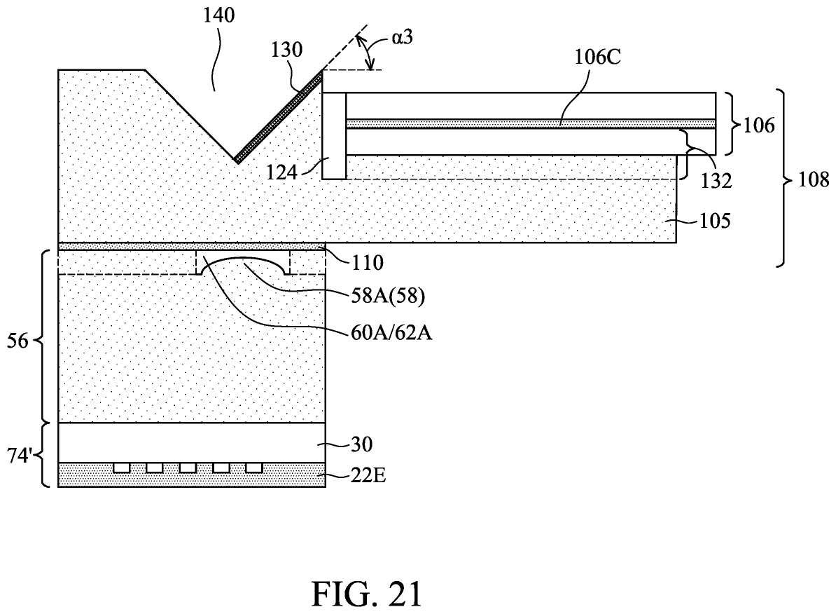

FIGS. 20 through 28 illustrate some portions (FIG. 12 or 14) of packages 76, and the illustrate portions include FAUs 108. The illustrated portions may or may not include supporting substrate 56 and photonic dies 74′. It is appreciated that although some features are shown in some embodiments but not in other embodiments, these features may (or may not) exist in other embodiments whenever possible. For example, although each of the illustrated example embodiments shows a specific combination of lenses, any other combinations of lenses may also be used whenever applicable. Also, each of the different combinations of lenses may be integrated with the curved reflector 130 (FIG. 20) or straight reflector 130 (FIGS. 21-23). For example, the package shown in FIGS. 21 through 23 may have a single lens, two lenses, three lenses, or four lenses in accordance with various embodiments.

FIG. 20 illustrates a portion of package 76 (FIGS. 12 and 14) in accordance with some embodiments. The structure in accordance with these embodiments is similar to the structure as shown in FIG. 17, except that lens 58B is also formed. Throughout the description, lens 58A, 58B, and other lenses 58C, 58D, 58E, and 58F as shown in subsequent figures are collectively referred to as lenses 58. In accordance with some embodiments, lens 58B is formed as a bottom portion of fiber platform 105. The formation process may also be similar to the formation of lens 58A. In accordance with some embodiments, lens 58B is formed in recess 60B, which extends from a bottom surface of fiber platform 105 upwardly. The recess 60B may be filled with an addition filling material 62B such as silicon oxide, or may be filled with index matching glue 110. In accordance with alternative embodiments, no index matching glue is used between fiber platform 105 and supporting substrate 56, and fiber platform 105 is in physical contact with supporting substrate 56.

In accordance with some embodiments, as shown in FIG. 20, lens 58B is vertically offset from lens 58A to suit to the slanted light path 122. The size of lens 58B may be equal to the size of lens 58A. Alternatively, the size of lens 58B may be larger than the size of lens 58A due to the situation that the light beam 128 received by lens 58A is more converged than the light beam received by lens 58B. Reflector 130 may be curved.

In accordance with some embodiments, in the cross-sectional view, reflector 130 may fit a circle, and different parts of reflector 130 may have equal distances to center 136 of the circle. Reflector 130 may also have the shape of a quarter of a circle in accordance with some embodiments. It is appreciated that FIG. 20 illustrates one of the vertical planes that is parallel to the lengthwise direction of optical fiber 106. In other planes that are parallel to the illustrated plane, the cross-sectional view shape of reflector 130 may also be the same as in the illustrated plane. Alternatively stated, when different cross-sectional views are obtained crossing different optical fibers 106, the shape of the reflector 130 in the different cross-sections are the same as each other.

In accordance with some embodiments, the straight line 138 interconnecting the opposite ends of reflector 130 has tilt angle θ3, which may be in the range between about 30 degrees and about 60 degrees, and may be equal to 45 degrees.

FIGS. 21, 22, and 23 illustrate portions of package 76 (FIGS. 12 and 14) in accordance with some embodiments. These embodiments are similar to the embodiments as shown in FIG. 20, except that reflector 130 is a planar-and-slant reflector. The reflector 130 has tilt angle θ3, which may be equal to or slightly smaller than 45 degrees. For example, tilt angle θ3 may be equal to about 44 degrees. Simulation results have revealed that with the tilt angle being slightly smaller than 45 degrees, such as equal to 44 degrees, the light intensity receiving rate, which is the ratio of the intensity of the light received by grating coupler 22E to the light intensity emitted out of optical fiber 106, is higher than the light receiving rate when the tilt angle is equal to all other angles (including 45 degrees).

FIG. 21 illustrates an embodiment in which reflector 130 is formed inside a recess in fiber platform 105, and is on one of the slanted sidewalls of recess 140, which has a V-shape in a cross-sectional view.

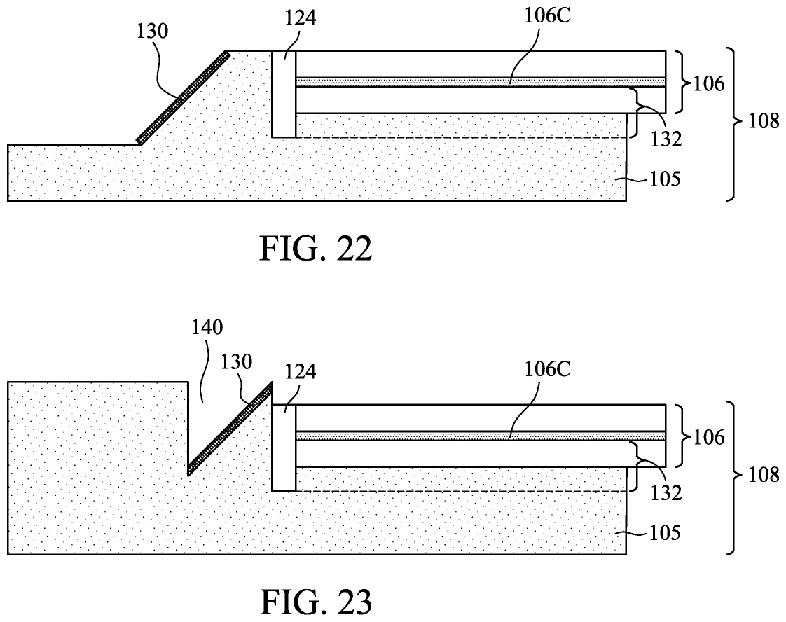

FIG. 22 illustrates an embodiment in which the portion of fiber platform 105 on the left side of reflector 130 is removed. Reflector 130 is thus formed on a slant sidewall of a protruding portion of fiber platform 105.

FIG. 23 illustrates an embodiment in which reflector 130 is formed inside a recess, and is on a slanted sidewall of recess 140. The portion of fiber platform 105 on the left side of reflector 130 has a vertical sidewall facing reflector 130.

FIG. 24 illustrates a portion of package 76 (FIGS. 12 and 14) in accordance with some embodiments. The structure in accordance with these embodiments is similar to the structure as shown in FIG. 20, except that reflector 130 is a planar-and-slant reflector. Also, two lenses 58A and 58B are formed facing each other.

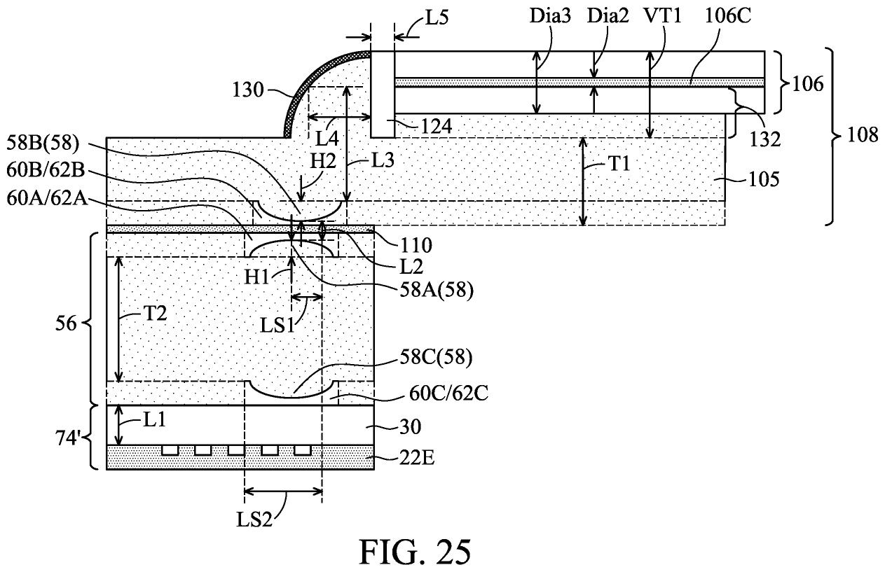

FIG. 25 illustrates a portion of package 76 (FIGS. 12 and 14) in accordance with some embodiments. The structure in accordance with these embodiments is similar to the structure as shown in FIG. 20, except that lens 58C is formed in addition to lenses 58A and 58B. Lens 58C is formed as a bottom portion of supporting substrate 56. The formation process may also be similar to the formation of lens 58A. In accordance with some embodiments, lens 58C is formed in recess 60C, which extends from a bottom surface of supporting substrate 56 upwardly. The recess 60C may be filled with an addition filling material 62C such as silicon oxide. In accordance with some embodiments, filling material 62C and the silicon in supporting substrate 56 are bonded to dielectric layer 30 in photonic die 74′ through fusion bonding.

Some example dimensions are discussed herein referring to FIG. 25. It is appreciated that the example dimensions may also apply to the corresponding features in other embodiments such as in FIGS. 17 and 20-24 and 26-28. The diameter Dia2 of the core 106C of optical fiber 106 may be in the range between about 8 μm and about 12 μm. The diameter Dia3 of protection layer 106P may be greater than about 100 μm. The vertical distance VT1 from the top of optical fiber 106 to the bottom of grooves 132 may be in the range between about 100 μm and about 150 μm. The thickness T1 of fiber platform 105, which is measured from the bottom of grooves 132 to the bottom planar surface of fiber platform 105, may be greater than about 500 μm, and may be in the range between 500 μm and about 700 μm. The thickness T2 of supporting substrate 56 may be in the range between 500 μm and about 900 μm.

Furthermore, the vertical spacing L1 between grating coupler 22E and supporting substrate 56 may be in the range between about 15 μm and about 35 μm. The vertical spacing L2 between lenses 58A and 58B may be in the range between about 5 μm and about 15 μm. The vertical spacing L3 from the middle point of reflector 130 to the bottom planar surface of fiber platform 105 may be in the range between about 500 μm and about 700 μm. The lateral spacing L4 from the middle point of reflector 130 to index matching glue 124 may be in the range between about 100 μm and about 150 μm. The thickness L5 of index matching glue 124 may be in the range between about 1 μm and about 5 μm.

The height H1 of lens 58A and height H2 of lens 58B may be in the range between about 1 μm and about 4 μm. The lateral offset LS1 between the center of reflector 130 and the center grating coupler 22E may be in the range between about 30 μm and about 50 μm. The lateral offset LS1 between the center of reflector 130 and the center of lens 58A may be greater than about 10 μm, about 25 μm, or about 50 μm. The lateral offset LS2 between the center of reflector 130 and the center of grating coupler 22E may also be in the range between about 30 μm and about 50 μm.

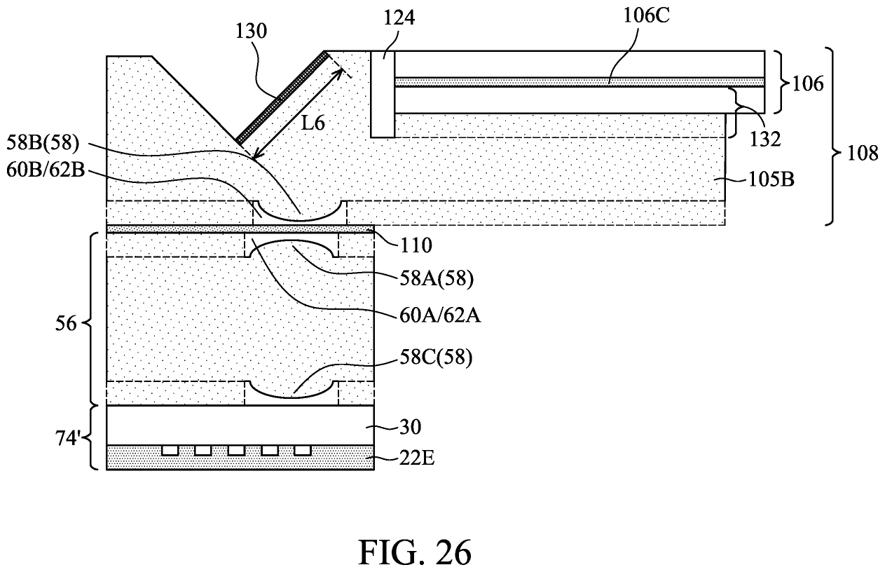

FIG. 26 illustrates a portion of package 76 (FIGS. 12 and 14) in accordance with some embodiments. The structure in accordance with these embodiments is similar to the structure as shown in FIG. 25, except that reflector 130 is a planar-and-tilted reflector rather than a curved reflector. The length L6 of reflector 130 may be in the range between about 100 μm and about 200 μm.

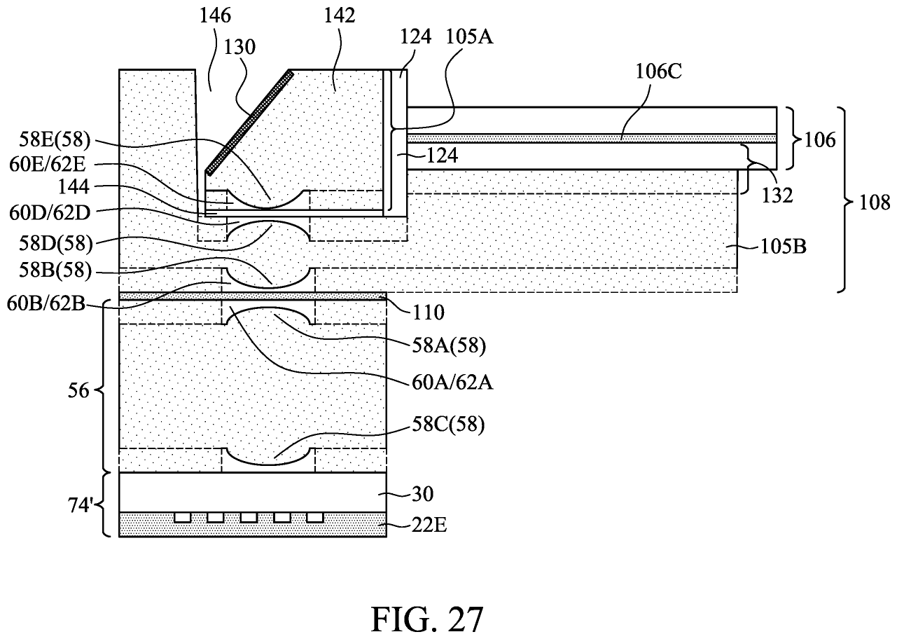

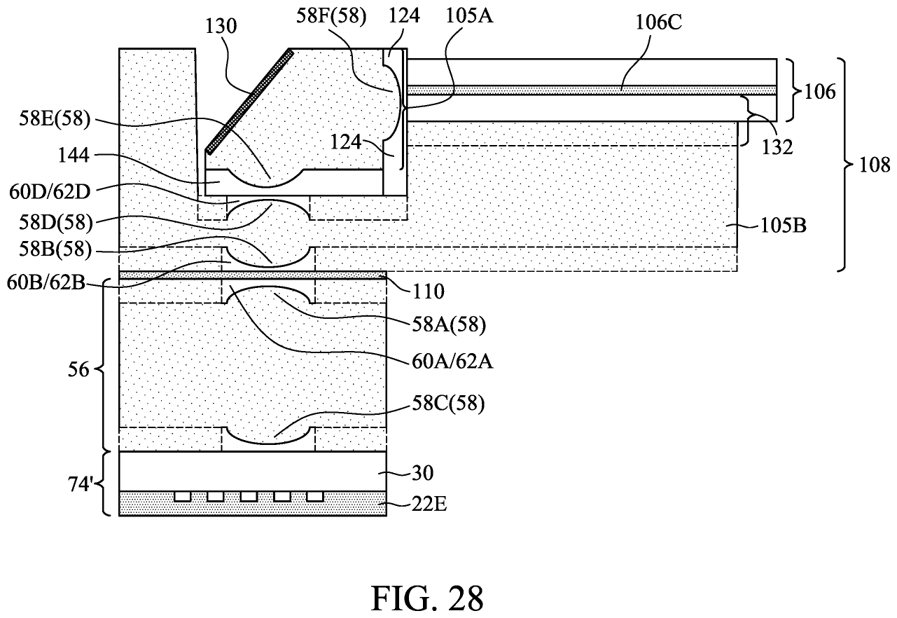

FIGS. 27 and 28 illustrate portions of package 76 (FIGS. 12 and 14) in accordance with some embodiments. The structures in accordance with these embodiments are similar to the structures as shown in FIG. 25, except that reflector 130 is formed in a discrete deflection module 105A, which is physically separated from groove frame 105B. Deflection module 105A and groove frame 105B collectively form fiber platform 105.

Deflection module 105A may include substrate 142, with reflector 130 being formed on substrate 142. Substrate 142 is formed of a transparent material such as silicon, glass, or the like. Reflector 130 may be a curved reflector (FIG. 25, for example), or may be a planar-and-slant reflector as illustrated in FIGS. 27 and 28. Deflection module 105A may be pre-formed as an integrated unit, and then inserted into the recess 146 in groove frame 105B. Index matching glues 124 and 144 may be dispensed to adhere deflection module 105A to groove frame 105B.

In accordance with some embodiments, lens 58D is formed as a bottom port of deflection module 105A. Lens 58E may be formed in recess 60E, which is a part of substrate 142. Lens 58E may be in a recess 60E in substrate 142, as shown in FIG. 27. The recess 60E may be filled with a filling material 62E such as silicon oxide, or may be filled by index matching glue 144. Alternatively, lens 58E may protrude below a bottom planar surface of substrate 142. Groove frame 105B may or may not include lens 58D, which may be in a recess 60D in groove frame 105B, as shown in FIG. 27. The recess 60D may be filled with a filling material 62D such as silicon oxide, or may be filled by index matching glue 144. Alternatively, lens 58D may protrude above a top planar surface of Groove frame 105B.

In accordance with some embodiments, deflection module 105A includes a straight sidewall (the illustrated right sidewall) facing optical fiber 106. The straight sidewall may be adopted when substrate 142 is a silicon substrate, while a lens 58E may also be formed to face optical fiber 106, similar to what is shown in FIG. 28.

FIG. 28 illustrates deflection module 105A in accordance with alternative embodiments, in which lens 58F is formed as a part of deflection module 105A. Lens 58F faces optical fiber 106. The substrate 142 in deflection module 105A as shown in FIG. 28 may be formed of glass, although silicon may also be used.

In each of the embodiments as shown in FIGS. 17 and 20-28, there may be one, two, three, four, five, or six lenses, which are selected from lenses 58A, 58B, 58C, 58D, 58E, and 58F in any combination. Also, the reflector 130 as illustrated may be a curved reflector or a planar-and-tilted reflector in combination with the different numbers of lenses. Furthermore, each of the lenses may be formed in a recess or may be formed as a protruding lens, wherein the dashed features represent the embodiments in which lens is in recesses, and the dashed features may or may not be formed.

The embodiments of the present disclosure have some advantageous features. By adopting the fiber deflection units, optical fibers may be attached to optical engines in a horizontal direction, and the light is deflected to a vertical direction by a reflector. It is much easier to attached a horizontally placed optical fiber than to attach a vertically placed optical fiber. If the optical fiber is attached vertically, it may to be tilted for a small angle, making the attachment more difficult. Also, the vertically attached optical fiber is more fragile than the horizontal attached optical fiber. By placing the optical fibers horizontally, it is also easy to increase the total number of optical fibers.

In accordance with some embodiments of the present disclosure, a method comprises forming an optical engine comprising a photonic die, wherein the photonic die comprises a grating coupler; forming a fiber unit comprising a fiber platform comprising a groove; an optical fiber attached to the fiber platform, wherein the optical fiber extends into the groove; and a reflector; and attaching the fiber unit to the optical engine, wherein the reflector is configured to deflect a light beam, so that the light beam emitted by a first one of the optical fiber and the grating coupler is received by a second one of the optical fiber and the grating coupler.

In an embodiment, the forming the optical engine comprises bonding a supporting substrate to the photonic die, wherein the supporting substrate comprises a first lens configured to converge the light beam. In an embodiment, a first center of the first lens is laterally offset from a second center of the reflector. In an embodiment, the supporting substrate further comprises a second lens configured to converge the light beam, wherein the first lens and the second lens are on opposite sides of the supporting substrate. In an embodiment, the forming the photonic die comprises patterning a top silicon layer in a substrate to form a plurality of photonic devices, wherein the substrate comprises the top silicon layer, a first dielectric layer under the top silicon layer, and a semiconductor layer under the first dielectric layer; forming a second dielectric layer to embed the plurality of photonic devices therein; forming an interconnect structure over and signally coupling to the plurality of photonic devices; and bonding an electronic die to the interconnect structure.

In an embodiment, the method further comprises removing the first dielectric layer and the semiconductor layer; forming backside dielectric layers and waveguides in the backside dielectric layers; and forming through-vias penetrating through the backside dielectric layers to electrically couple to the interconnect structure. In an embodiment, the fiber unit comprises a lens located in a light path of the light beam, and wherein the lens is configured to converge the light beam. In an embodiment, the reflector is curved. In an embodiment, the reflector fits a circle in a cross-sectional view of the fiber unit. In an embodiment, the reflector is planar-and-tilted.

In an embodiment, the fiber unit comprises a plurality of grooves, with the groove being one of the plurality of grooves; and a plurality of optical fibers extending into the plurality of grooves, with the optical fiber being one of the plurality of optical fibers. In an embodiment, the attaching the fiber unit to the optical engine comprises attaching the fiber unit to a supporting substrate in the optical engine, wherein the fiber unit is further attached to a metal lid that encircles the optical engine, and wherein the fiber unit extends into an opening in the metal lid.

In accordance with some embodiments of the present disclosure, a package comprises a photonic die comprising a grating coupler; a supporting substrate over the photonic die, wherein the supporting substrate comprises a first lens; and a fiber deflection unit attached to the supporting substrate, wherein the fiber deflection unit comprises a fiber platform; a reflector on a sidewall of the fiber platform; a groove in the fiber platform; and an optical fiber extending into the groove. In an embodiment, the reflector is configured to deflect a light beam emitted from the optical fiber and traveling in a horizontal direction to a vertical direction and to the grating coupler. In an embodiment, the reflector is configured to deflect a light beam emitted from the grating coupler and traveling in a vertical direction to a horizontal direction and to the optical fiber. In an embodiment, the reflector is curved. In an embodiment, the reflector is straight-and-slanted.

In accordance with some embodiments of the present disclosure, a package comprises an optical engine comprising a photonic device; and a lens over the photonic device; a metal lid, wherein the optical engine is covered by a top portion of the metal lid; and a fiber deflection unit extending partially into the metal lid, wherein the fiber deflection unit is configured to emit a light beam horizontally out of an optical fiber in the fiber deflection unit; and deflect the light beam to the lens, wherein the light beam is further projected to the photonic device. In an embodiment, the fiber deflection unit comprises a reflector for deflecting the light beam, and wherein the reflector comprises a metal, and has a curved shape. In an embodiment, the optical engine comprises a photonic die; and a supporting substrate over and bonding to the photonic die, wherein the lens is in the supporting substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an optical engine comprising a photonic die, wherein the photonic die comprises a grating coupler;
forming a fiber unit comprising:
a fiber platform comprising a groove;
an optical fiber attached to the fiber platform, wherein the optical fiber extends into the groove; and
a reflector; and
attaching the fiber unit to the optical engine, wherein the reflector is configured to deflect a light beam, so that the light beam emitted by a first one of the optical fiber and the grating coupler is received by a second one of the optical fiber and the grating coupler.

2. The method of claim 1, wherein the forming the optical engine comprises bonding a supporting substrate to the photonic die, wherein the supporting substrate comprises a first lens configured to converge the light beam.

3. The method of claim 2, wherein a first center of the first lens is laterally offset from a second center of the reflector.

4. The method of claim 2, wherein the supporting substrate further comprises a second lens configured to converge the light beam, wherein the first lens and the second lens are on opposite sides of the supporting substrate.

5. The method of claim 1, wherein the forming the photonic die comprises:
patterning a top silicon layer in a substrate to form a plurality of photonic devices, wherein the substrate comprises the top silicon layer, a first dielectric layer under the top silicon layer, and a semiconductor layer under the first dielectric layer;
forming a second dielectric layer to embed the plurality of photonic devices therein;
forming an interconnect structure over and signally coupling to the plurality of photonic devices; and
bonding an electronic die to the interconnect structure.

6. The method of claim 5 further comprising:
removing the first dielectric layer and the semiconductor layer;
forming backside dielectric layers and waveguides in the backside dielectric layers; and
forming through-vias penetrating through the backside dielectric layers to electrically couple to the interconnect structure.

7. The method of claim 1, wherein the fiber unit comprises a lens located in a light path of the light beam, and wherein the lens is configured to converge the light beam.

8. The method of claim 1, wherein the reflector is curved.

9. The method of claim 8, wherein the reflector fits a circle in a cross-sectional view of the fiber unit.

10. The method of claim 1, wherein the reflector is planar-and-tilted.

11. The method of claim 1, wherein the fiber unit comprises:
a plurality of grooves, with the groove being one of the plurality of grooves; and
a plurality of optical fibers extending into the plurality of grooves, with the optical fiber being one of the plurality of optical fibers.

12. The method of claim 1, wherein the attaching the fiber unit to the optical engine comprises attaching the fiber unit to a supporting substrate in the optical engine, wherein the fiber unit is further attached to a metal lid that encircles the optical engine, and wherein the fiber unit extends into an opening in the metal lid.

13. A package comprising:
a photonic die comprising a grating coupler;
a supporting substrate over the photonic die, wherein the supporting substrate comprises a first lens; and
a fiber deflection unit attached to the supporting substrate, wherein the fiber deflection unit comprises:
a fiber platform;
a reflector on a sidewall of the fiber platform;
a groove in the fiber platform; and
an optical fiber extending into the groove.

14. The package of claim 13, wherein the reflector is configured to deflect a light beam emitted from the optical fiber and traveling in a horizontal direction to a vertical direction and to the grating coupler.

15. The package of claim 13, wherein the reflector is configured to deflect a light beam emitted from the grating coupler and traveling in a vertical direction to a horizontal direction and to the optical fiber.

16. The package of claim 13, wherein the reflector is curved.

17. The package of claim 13, wherein the reflector is straight-and-slanted.

18. A package comprising:
an optical engine comprising:
a photonic device; and
a lens over the photonic device;
a metal lid, wherein the optical engine is covered by a top portion of the metal lid; and
a fiber deflection unit extending partially into the metal lid, wherein the fiber deflection unit is configured to:
emit a light beam horizontally out of an optical fiber in the fiber deflection unit; and
deflect the light beam to the lens, wherein the light beam is further projected to the photonic device.

19. The package of claim 18, wherein the fiber deflection unit comprises a reflector for deflecting the light beam, and wherein the reflector comprises a metal, and has a curved shape.

20. The package of claim 18, wherein the optical engine comprises:
a photonic die; and
a supporting substrate over and bonding to the photonic die, wherein the lens is in the supporting substrate.
